(19) United States
(12) Patent Application Publication
(10) Pub. No.: US 2025/0180381 A1
(43) Pub. Date: Jun. 5, 2025

(54) DISTANCE MEASUREMENT METHOD, DISTANCE MEASUREMENT SYSTEM, AND SUBSTRATE PROCESSING APPARATUS

(71) Applicant: Tokyo Electron Limited, Tokyo (JP)

(72) Inventor: Tomohiro YAMANOUE, Koshi City (JP)

(21) Appl. No.: 18/962,032

(22) Filed: Nov. 27, 2024

(30) Foreign Application Priority Data
Dec. 1, 2023 (JP) 2023-203626

(51) Int. Cl. G01D 5/24; H01L 21/677; H01L 21/68

(52) U.S. Cl. CPC G01D 5/24; H01L 21/67739; H01L 21/68

(57) ABSTRACT

A distance measurement method includes: heating a processing container capable of accommodating a substrate; loading a jig of a substrate shape into the processing container in a state in which the processing container is heated; and measuring a distance from the jig to a ceiling surface of the processing container by using a distance sensor provided in the jig.

### CROSS-REFERENCE TO RELATED APPLICATION

This application is based upon and claims the benefit of priority from Japanese Patent Application No. 2023-203626, filed on Dec. 1, 2023, the entire contents of which are incorporated herein by reference.

### TECHNICAL FIELD

The present disclosure relates to a distance measurement method, a distance measurement system, and a substrate processing apparatus.

### BACKGROUND

Conventionally, a supercritical drying technique which dries a substrate by using a supercritical fluid obtained under a high temperature and high pressure environment formed within a processing container has been known as a technique for removing moisture remaining on a surface of the substrate while suppressing pattern collapse.

### PRIOR ART DOCUMENT

### Patent Document

Patent Document 1: Japanese Patent Laid-Open Publication No. 2022-121188

### SUMMARY

According to one embodiment of the present disclosure, there is provided a distance measurement method including: heating a processing container capable of accommodating a substrate; loading a jig of a substrate shape into the processing container in a state in which the processing container is heated; and measuring a distance from the jig to a ceiling surface of the processing container by using a distance sensor provided in the jig.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view of a substrate processing system according to an embodiment as viewed from above.

FIG. 2 is a schematic cross-sectional view of the substrate processing system according to the embodiment as viewed from a side.

FIG. 3 is a flowchart showing a series of substrate processing processes executed in the substrate processing system according to the embodiment.

FIG. 4 is a diagram showing an example of a configuration of a liquid processing unit.

FIG. 5 is a schematic cross-sectional view showing an example of a configuration of a drying unit.

FIG. 6 is a schematic cross-sectional view showing an example of a state in which a wafer is accommodated inside a processing container.

FIG. 7 is a schematic plan view showing a configuration of a jig according to an embodiment.

FIG. 8 is a schematic cross-sectional view showing the configuration of the jig according to the embodiment.

FIG. 9 is a diagram showing an example of a measurement operation using the jig according to the embodiment.

FIG. 10 is a diagram showing an example of a measurement operation using the jig according to the embodiment.

FIG. 11 is a diagram showing an example of a measurement operation using the jig according to the embodiment.

FIG. 12 is a diagram showing an example of a correction operation on a measured value from a distance sensor according to an embodiment.

FIG. 13 is a diagram showing an example of a reading operation of the measured value from the jig according to the embodiment.

FIG. 14 is a flowchart showing an example of a flow of a distance measurement process according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment for implementing a distance measurement method, a distance measurement system, and a substrate processing apparatus according to the present disclosure (hereinafter referred to as an “embodiment”) is described in detail with reference to the accompanying drawings. The present disclosure is not limited by the embodiment. Further, embodiments may be appropriately combined as long as the contents of processes are not contradictory. Furthermore, in the following embodiments, same parts are assigned the same reference numerals and repeated description is omitted.

Conventionally, a supercritical drying technique which dries a substrate by using a supercritical fluid obtained under a high temperature and high pressure environment formed within a processing container has been known as a technique for removing moisture remaining on a surface of the substrate while suppressing pattern collapse.

However, in the supercritical drying technique, if a distance from the substrate to a ceiling surface of the processing container deviates from an appropriate distance, a flow of the supercritical fluid between the substrate and the ceiling surface of the processing container is disturbed, and thus, there is a concern that the suppression of pattern collapse and efficiency of moisture removal may be reduced. For this reason, a realization of a technique that appropriately measures a distance from the substrate to the ceiling surface of the processing container is expected.

### 1. Configuration of Substrate Processing System

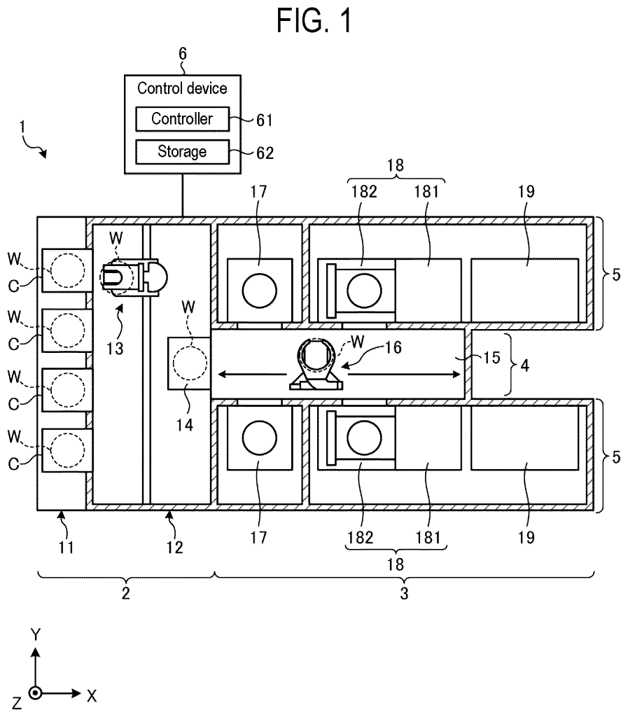

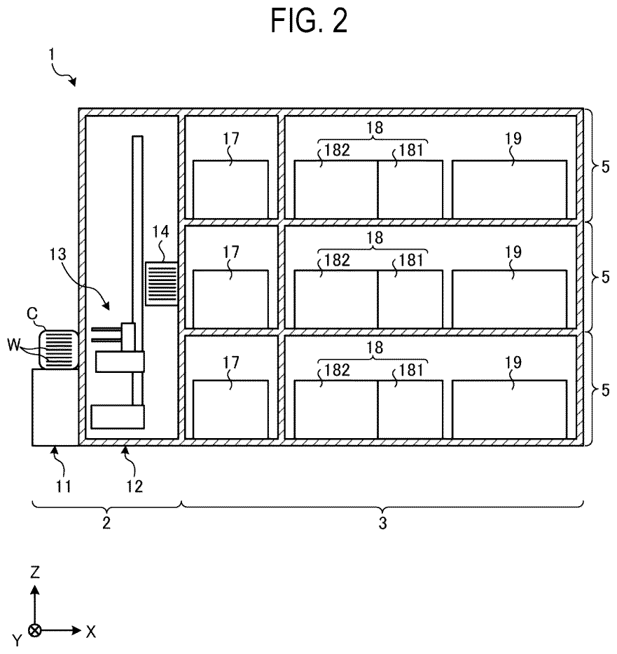

First, a configuration of a substrate processing system (an example of a distance measurement system and a substrate processing apparatus) according to an embodiment is described with reference to FIGS. 1 and 2. FIG. 1 is a schematic cross-sectional view of the substrate processing system according to the embodiment as viewed from above. FIG. 2 is a schematic cross-sectional view of the substrate processing system according to the embodiment as viewed from a side. To clearly describe a positional relationship, an X axis, a Y axis, and a Z axis which are orthogonal to one another are defined and a positive direction of the Z axis is defined as a vertical upward direction.

As shown in FIG. 1, the substrate processing system 1 includes a loading/unloading station 2 and a processing station 3. The loading/unloading station 2 and the processing station 3 are provided adjacent to each other.

### Regarding Loading/Unloading Station 2

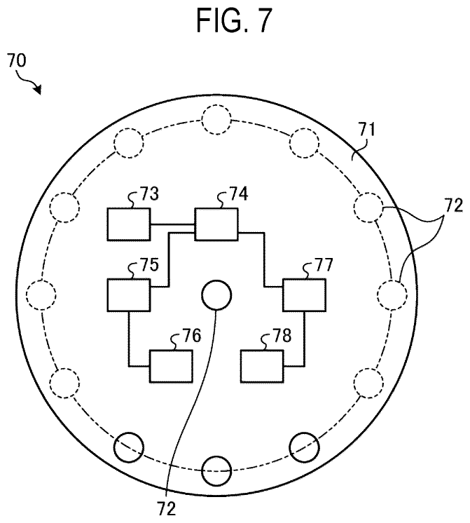

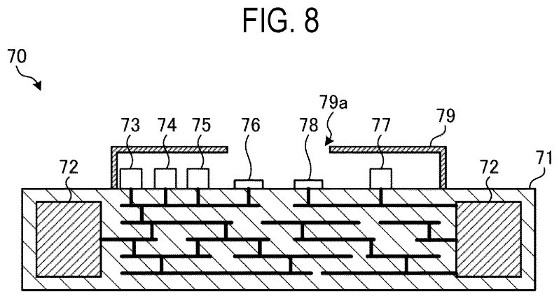

The loading/unloading station 2 includes a carrier placement portion 11 and a transfer portion 12. A plurality of carriers C, each of which accommodates a plurality of semiconductor wafers W (hereinafter referred to as “wafers W”) in a horizontal posture, are placed on the carrier placement portion 11. In the carrier C, a jig 70 (see FIGS. 7 and 8) described later may be accommodated.

The transfer portion 12 is provided adjacent to the carrier placement portion 11. A transfer device 13 and a delivery portion 14 are disposed inside the transfer portion 12.

The transfer device 13 includes a wafer holder that holds the wafers W. The transfer device 13 may move in horizontal and vertical directions and may rotate about a vertical axis. The transfer device 13 transfers the wafers W between the carriers C and the delivery portion 14 by using the wafer holder.

### Regarding Processing Station 3

The processing station 3 is provided adjacent to the transfer portion 12. The processing station 3 includes a transfer block 4 and a plurality of processing blocks 5.

### Regarding Transfer Block 4

The transfer block 4 includes a transfer area 15 and a transfer device 16. The transfer area 15 is, for example, a rectangular parallelepiped area extending in an arrangement direction (an X-axis direction) of the loading/unloading station 2 and the processing station 3. The transfer device 16 is disposed in the transfer area 15.

The transfer device 16 includes a wafer holder for holding the wafers W. The transfer device 16 may move in horizontal and vertical directions and rotate around a vertical axis. The transfer device 16 transfers the wafers W between the delivery portion 14 and the processing blocks 5 by using the wafer holder.

### Regarding Arrangement of Processing Blocks 5

The plurality of processing blocks 5 are disposed adjacent to the transfer area 15 on both sides of the transfer area 15. Specifically, the plurality of processing blocks 5 are disposed on one side (a positive direction of the Y axis) and the other side (a negative direction of the Y axis) of the transfer area 15 in a direction (a Y-axis direction) perpendicular to the arrangement direction (the X-axis direction) of the loading/unloading station 2 and the processing station 3.

As shown in FIG. 2, the plurality of processing blocks 5 are arranged in multiple stages in the vertical direction. In this embodiment, the number of stages of the processing blocks 5 is three, but the number of stages of the processing blocks 5 is not limited to three.

Thus, in the substrate processing system 1 according to the embodiment, the processing blocks 5 are disposed in multiple stages on both sides of the transfer block 4. Then, transfers of the wafers W between the processing block 5 disposed in each stage and the delivery portion 14 is performed by one transfer device 16 disposed in the transfer block 4.

### Regarding Internal Configuration of Processing Block 5

Each processing block 5 includes a liquid processing unit 17, a drying unit 18, and a supply unit 19.

The liquid processing unit 17 performs a cleaning process for cleaning an upper surface of the wafer W, which is a pattern formation surface. The liquid processing unit 17 also performs a liquid film forming process for forming a liquid film on the upper surface of the wafer W after the cleaning process. A configuration of the liquid processing unit 17 is described later.

The drying unit 18 performs a supercritical drying process on the wafer W after the liquid film forming process. Specifically, the drying unit 18 dries the wafer W after the liquid film forming process by contacting the wafer W after the liquid film forming process with a processing fluid in a supercritical state. A configuration of the drying unit 18 is described later.

The supply unit 19 supplies the processing fluid to the drying unit 18. Specifically, the supply unit 19 includes a supplier group including a flow-rate meter, a flow-rate regulator, a back pressure valve, a heater, etc., and includes a housing accommodating the supplier group. In this embodiment, the supply unit 19 supplies CO₂ as the processing fluid to the drying unit 18.

The liquid processing unit 17, the drying unit 18, and the supply unit 19 are arranged along the transfer area 15 (i.e., in the X-axis direction). Among the liquid processing unit 17, the drying unit 18, and the supply unit 19, the liquid processing unit 17 is disposed at a position closest to the loading/unloading station 2, and the supply unit 19 is disposed at a position farthest from the loading/unloading station 2.

Thus, each processing block 5 includes one liquid processing unit 17, one drying unit 18, and one supply unit 19. That is, the substrate processing system 1 is provided with the same number of liquid processing units 17, transfer devices 16, and supply units 19.

The drying unit 18 includes a processing area 181 in which a supercritical drying process is performed and a delivery area 182 in which the wafer W is delivered between the transfer block 4 and the processing area 181. The processing area 181 and the delivery area 182 are arranged along the transfer area 15.

Specifically, among the processing area 181 and the delivery area 182, the delivery area 182 is disposed closer to the liquid processing unit 17 than the processing area 181. That is, in each processing block 5, the liquid processing unit 17, the delivery area 182, the processing area 181, and the supply unit 19 are disposed in this order along the transfer area 15.

### Regarding Control Device 6

The substrate processing system 1 includes a control device 6. The control device 6 is, for example, a computer, and includes a controller 61 and a storage 62.

The controller 61 includes a microcomputer having a central processing unit (CPU), a read only memory (ROM), a random access memory (RAM), an input/output port, and the like or includes various circuits. The CPU of the microcomputer controls the transfer devices 13 and 16, the liquid processing unit 17, the drying unit 18, and the supply unit 19 by reading and executing programs stored in the ROM.

Further, such programs may be recorded by the computer in a computer-readable storage medium and installed from the storage medium into the storage 62 of the control device 6. The computer-readable storage medium includes, for example, a hard disk (HD), a flexible disk (FD), a compact disc (CD), a magneto-optical (MO) disk, a memory card, and the like.

The storage 62 is realized by, for example, a semiconductor memory element such as a RAM or a flash memory, or a storage device such as an HD or an optical disc.

### 2. Flow of Substrate Processing

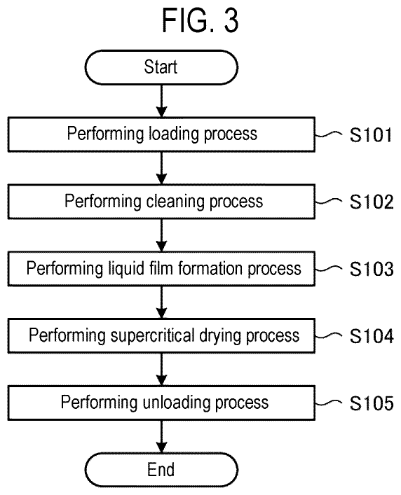

Next, a flow of a series of substrate processing processes in the above-described substrate processing system 1 is described with reference to FIG. 3. FIG. 3 is a flowchart showing a series of substrate processing processes executed in the substrate processing system 1 according to the embodiment. The series of substrate processing processes shown in FIG. 3 is executed according to control of the controller 61.

As shown in FIG. 3, in the substrate processing system 1, first, a loading process is performed (step S101). In the loading process, the transfer device 13 (see FIG. 1) takes a wafer W out of the carrier C and places the wafer W on the delivery portion 14. Next, the transfer device 16 (see FIG. 1) takes the wafer W out of the delivery portion 14 and loads the wafer W into the liquid processing unit 17.

Next, in the substrate processing system 1, a cleaning process is performed in the liquid processing unit 17 (step S102). The liquid processing unit 17 removes particles, natural oxide films, and the like from the upper surface of the wafer W by supplying various types of processing liquids to the upper surface of the wafer W, which is the pattern formation surface.

Next, in the substrate processing system 1, a liquid film forming process is performed in the liquid processing unit 17 (step S103). The liquid processing unit 17 supplies IPA in a liquid state (hereinafter referred to as an “IPA liquid”) to the upper surface of the wafer W after the cleaning process, thereby forming a liquid film on the upper surface of the wafer W by the IPA liquid.

The wafer W after the liquid film forming process is transferred by the transfer device 16 to the delivery area 182 of the drying unit 18 disposed in the same processing block 5. The wafer W, transferred to the delivery area 182 after the liquid film forming process, is transferred from the delivery area 182 to the processing area 181.

Thereafter, in the substrate processing system 1, a supercritical drying process is performed in the processing area 181 (step S104). In the supercritical drying process, the drying unit 18 dries the wafer W after the liquid film forming process by contacting the wafer W after the liquid film forming process with a processing fluid in a supercritical state.

Next, in the substrate processing system 1, an unloading process is performed (step S105). In the unloading process, first, the wafer W after the supercritical drying process is transferred from the processing area 181 to the delivery area 182. Then, the transfer device 16 takes the wafer W after the supercritical drying process out of the delivery area 182 and transfers the wafer W to the delivery portion 14. Then, the transfer device 13 takes the wafer W after the supercritical drying process out of the delivery portion 14 and transfers the wafer W to the carrier C. When the unloading process is completed, the series of substrate processing processes for one wafer W is completed.

### 3. Configuration of Liquid Processing Unit

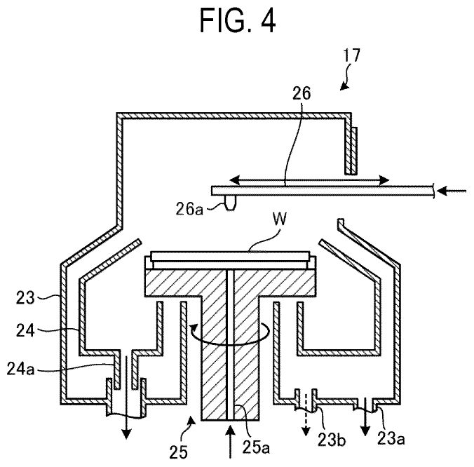

Next, a configuration of the liquid processing unit 17 is described with reference to FIG. 4. FIG. 4 is a diagram showing an example of the configuration of the liquid processing unit 17. The liquid processing unit 17 is configured as a single-wafer cleaning device that cleans the wafers W one by one by, for example, spin cleaning.

As shown in FIG. 4, the liquid processing unit 17 holds the wafer W almost horizontally by a wafer holder 25 disposed in an outer chamber 23 forming a processing space and rotates the wafer W by rotating the wafer holder 25 around a vertical axis. The liquid processing unit 17 performs the cleaning process on the upper surface of the wafer W by introducing a nozzle arm 26 above the rotating wafer W and supplying a chemical liquid or a rinsing liquid in a predetermined order from a chemical liquid nozzle 26a provided at a tip of the nozzle arm 26.

Further, in the liquid processing unit 17, a chemical liquid supply path 25a is formed inside the wafer holder 25. A lower surface of the wafer W is also cleaned by a chemical liquid or a rinsing liquid supplied from the chemical liquid supply path 25a.

In the cleaning process, for example, first, particles or organic contaminants are removed using SC1 liquid (a mixture of ammonia and hydrogen peroxide), which is an alkaline chemical liquid. Next, rinsing is performed using deionized water (hereinafter referred to as “DIW”), which is a rinsing liquid. Next, a natural oxide film is removed using diluted hydrofluoric acid (hereinafter referred to as “DHF”), which is an acidic chemical liquid. Thereafter, rinsing is performed using DIW.

The above-described various chemical liquids are accommodated in the outer chamber 23 or in an inner cup 24 disposed in the outer chamber 23 and are discharged from a drain port 23a provided at a bottom of the outer chamber 23 or from a drain port 24a provided at a bottom of the inner cup 24. Further, an atmosphere in the outer chamber 23 is exhausted from an exhaust port 23b provided at the bottom of the outer chamber 23.

The liquid film forming process is performed after the rinsing process of the cleaning process. Specifically, the liquid processing unit 17 supplies the IPA liquid to the upper and lower surfaces of the wafer W while rotating the wafer holder 25. Thereby, DIW remaining on both sides of the wafer W is replaced with IPA. Thereafter, the liquid processing unit 17 gently stops rotation of the wafer holder 25.

The wafer W after the liquid film forming process is delivered to the transfer device 16 by a delivery mechanism (not shown) provided at the wafer holder 25, with a liquid film of the IPA liquid formed on the upper surface of the wafer W, and is unloaded from the liquid processing unit 17. The liquid film formed on the wafer W prevents pattern collapse that occurs as a result of evaporation (vaporization) of liquid on the upper surface of the wafer W during transfer of the wafer W from the liquid processing unit 17 to the drying unit 18 or during a loading operation into the drying unit 18.

### 4. Configuration of Drying Unit

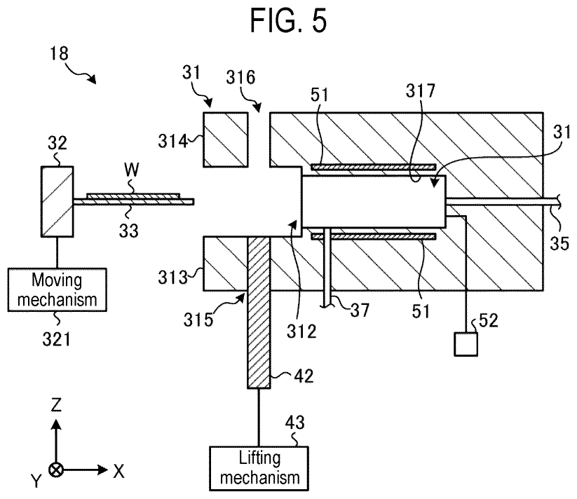

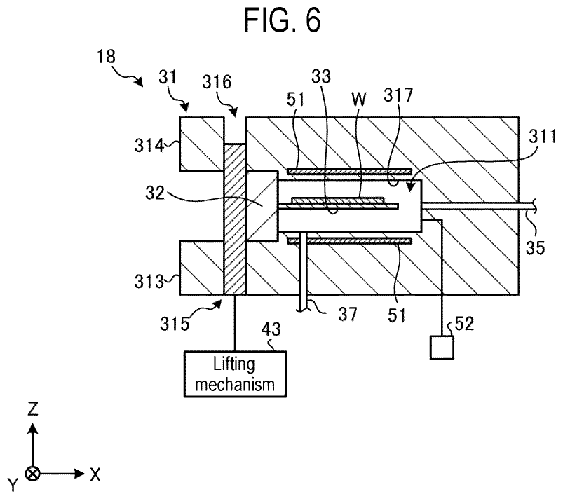

A configuration of the drying unit 18 is described with reference to FIGS. 5 and 6. FIG. 5 is a schematic cross-sectional view showing an example of the configuration of the drying unit 18. FIG. 6 is a schematic cross-sectional view showing an example of a state in which the wafer W is accommodated inside a processing container.

As shown in FIG. 5, the drying unit 18 includes a processing container 31, a lid 32, and a holder 33.

The processing container 31 is a pressure container capable of forming a high-pressure environment of, for example, about 16 to 20 MPa. The processing container 31 is disposed in the processing area 181 (see FIG. 1), and the supercritical drying process is performed in a processing space 311 inside the processing container 31. An opening 312 that communicates between the processing space 311 and the delivery area 182 (see FIG. 1) is formed on a side of the processing container 31 facing the delivery area 182.

The lid 32 is connected to a moving mechanism 321 and is moved horizontally between the processing area 181 and the delivery area 182 by the moving mechanism 321. In this way, the lid 32 opens and closes the opening 312 of the processing container 31.

The holder 33 holds the wafer W in a horizontal direction. The holder 33 is, for example, a frame having a rectangular shape when viewed in a plan view and holds the wafer W by supporting an outer periphery of the wafer W from below. The holder 33 is fixed to the lid 32.

As the holder 33 is moved to the processing area 181 together with the lid 32 by the moving mechanism 321, the holder 33 is accommodated in the processing space 311. As the holder 33 is accommodated in the processing space 311, the wafer W held by the holder 33 is loaded into the processing space 311.

The processing container 31 is provided with a supplier 35 and a discharger 37. The supplier 35 is connected to the supplier group of the supply unit 19 (see FIG. 1) and supplies the processing fluid from the supply unit 19 to the processing space 311. The discharger 37 discharges the processing fluid from the processing space 311.

The supplier 35 is provided on a side of the processing container 31 opposite to the side on which the opening 312 of the processing space 311 is formed. The supplier 35 horizontally supplies the processing fluid to the processing space 311 from a supply port that opens laterally.

The discharger 37 is provided at a bottom of the processing space 311 in the processing container 31. The discharger 37 discharges the processing fluid from a discharge port that opens upwards.

The drying unit 18 discharges the processing fluid in the processing space 311 via the discharger 37 while supplying the processing fluid from the supplier 35 to the processing space 311. A damper that adjusts a discharge amount of the processing fluid from the processing space 311 is provided at a discharge path of the processing fluid, and the discharge amount of the processing fluid is adjusted by the damper so that a pressure in the processing space 311 is adjusted to a desired pressure. Thereby, a supercritical state of the processing fluid is maintained in the processing space 311. Hereinafter, the processing fluid in a supercritical state may be referred to as a “supercritical fluid.”

The processing container 31 includes a first protrusion 313 and a second protrusion 314 that protrude further in a lid opening direction of the opening 312 from the opening 312. The first protrusion 313 protrudes from a lower portion of the opening 312 in the X-axis direction, and the second protrusion 314 protrudes from an upper portion of the opening 312 in the X-axis direction.

The first protrusion 313 is formed with a first insertion through-hole 315 that communicates with an upper surface and a lower surface of the first protrusion 313. In addition, the second protrusion 314 is formed with a second insertion through-hole 316 that communicates with an upper surface and a lower surface of the second protrusion 314 at a position facing the first insertion through-hole 315 in a vertical direction (i.e., above the first insertion through-hole 315).

The drying unit 18 further includes a lock member 42. The lock member 42 is inserted through the first insertion through-hole 315 formed at the first protrusion 313. A lifting mechanism 43 that moves the lock member 42 in the vertical direction is connected to the lock member 42.

The drying unit 18 further includes a plurality of heaters 51 (two heaters in this embodiment) and a temperature sensor 52. The heaters 51 are disposed above and below the processing space 311 of the processing container 31 with the processing space 311 interposed therebetween and heat the processing space 311 according to control of the controller 61. The temperature sensor 52 measures a temperature of the processing space 311 of the processing container 31 and outputs a measured result to the controller 61.

In the drying unit 18, first, a loading process of the wafer W is performed. In the loading process, the drying unit 18 horizontally moves the lid 32 in a positive direction of the X axis by the moving mechanism 321. As a result, the wafer W held by the holder 33 is accommodated in the processing space 311 of the processing container 31, and the processing space 311 is sealed by the lid 32 (see FIG. 6).

In addition, the drying unit 18 raises the lock member 42 by the lifting mechanism 43, thereby inserting the lock member 42 into the second insertion through-hole 316 formed at the second protrusion 314.

The lock member 42 presses the lid 32 toward the processing space 311 against an internal pressure caused by the processing fluid supplied to the processing space 311. Thereby, it is possible to maintain a state in which the processing space 311 is sealed by the lid 32.

Next, in the drying unit 18, a pressure raising process is performed. In the pressure raising process, the drying unit 18 raises the pressure of the processing space 311 by supplying the processing fluid from the supplier 35 to the processing space 311 of the processing container 31. Thereby, the pressure of the processing space 311 is raised to a processing pressure from an atmospheric pressure. The processing pressure is a pressure that exceeds a threshold pressure (about 7.2 MPa) at which CO₂, which is the processing fluid, becomes supercritical and is, for example, about 16 MPa. By this pressure raising process, the phase of the processing fluid in the processing space 311 changes into the supercritical state, and the IPA liquid formed as the liquid film on the surface of the wafer W begins to dissolve into the supercritical processing fluid. In addition, the processing fluid supplied from the supply unit 19 may be in the supercritical state or in a liquid state.

Next, in the drying unit 18, a circulation process is performed. In the circulation process, the drying unit 18 supplies heated processing fluid from the supplier 35 to the processing space 311 while maintaining the pressure of the processing space 311 at the processing pressure and discharges the processing fluid supplied to the processing space 311 to an outside of the processing space 311 from the discharger 37. As a result, a laminar flow of the processing fluid flowing in a predetermined direction around the wafer W is formed in the processing space 311. The processing space 311 is heated to a predetermined temperature by the heated processing fluid.

The IPA liquid present on the pattern formation surface (upper surface) of the wafer W gradually dissolves in the supercritical fluid by contacting the supercritical fluid of a high pressure state (e.g., 16 MPa) and is finally replaced with the supercritical fluid. As a result, gaps between patterns are filled with the supercritical fluid.

Next, a pressure reducing process is performed in the drying unit 18. In the pressure reducing process, the drying unit 18 reduces the pressure of the processing space 311 from the high pressure state to the atmospheric pressure. As a result, the supercritical fluid with which the gaps between the patterns have been filled changes to a normal, i.e., gaseous, processing fluid. In this way, the IPA liquid between the patterns is removed, and the drying process of the wafer W is completed.

Herein, while the IPA liquid has been used as a liquid for preventing drying, and CO₂ has been used as the processing fluid, liquids other than the IPA may be used as the liquid for preventing drying, and fluids other than CO₂ may be used as the processing fluid.

However, in the supercritical drying process, if a distance from the wafer W to a ceiling surface 317 of the processing container 31 deviates from an appropriate distance, a flow of the supercritical fluid between the wafer W and the ceiling surface 317 is disturbed, and this reduces the suppression of pattern collapse and the efficiency of moisture removal. For example, the distance from the wafer W to the ceiling surface 317 of the processing container 31 may deviate from the appropriate distance due to thermal deformation of the processing container 31. For this reason, a realization of a technique that appropriately measures the distance from the wafer W to the ceiling surface 317 of the processing container 31 is expected.

Therefore, in the substrate processing system 1 according to the embodiment, the jig 70 of a substrate shape is loaded into the processing container 31 in a state in which the processing container 31 is heated, and a distance sensor provided in the jig 70 measures a distance from the jig 70 to the ceiling surface of the processing container 31.

This makes it possible to measure the distance from the jig 70 to the ceiling surface 317 of the processing container 31 with thermal deformation of the processing container 31 taken into account. Since the jig 70 has substantially the same shape as the wafer W, which is a product substrate, the distance from the jig 70 to the ceiling surface 317 of the processing container 31 may be regarded as the distance from the wafer W to the ceiling surface 317 of the processing container 31. Therefore, according to the substrate processing system 1 of the embodiment, it is possible to appropriately measure the distance from the wafer W to the ceiling surface 317 of the processing container 31.

### 5. Configuration of Jig

Next, a configuration of the jig 70 is described with reference to FIGS. 7 and 8. FIG. 7 is a schematic plan view showing the configuration of the jig 70 according to an embodiment, and FIG. 8 is a schematic cross-sectional view showing the configuration of the jig 70 according to the embodiment.

As shown in FIGS. 7 and 8, the jig 70 includes a base substrate 71, distance sensors 72, a temperature sensor 73, a control circuit 74, a memory 75, a reading pad 76, a battery 77, a charging pad 78, and a cover 79. For convenience of explanation, the cover 79 is omitted in FIG. 7.

The base substrate 71 has approximately the same shape as the wafer W, which is the product substrate. The base substrate 71 has a disc shape with a diameter of about 300 mm, for example. However, the base substrate 71 may have dimensions other than the above dimension. Materials of the base substrate 71 may include, for example, silicon, carbon fiber, quartz glass, silicon carbide, silicon nitride, alumina, etc. The distance sensors 72 are embedded inside the base substrate 71, and the temperature sensor 73, the control circuit 74, the memory 75, the reading pad 76, the battery 77, and the charging pad 78 are mounted on a surface of the base substrate 71. The distance sensors 72, the temperature sensor 73, the control circuit 74, the memory 75, the reading pad 76, the battery 77, and the charging pad 78 are appropriately connected by wiring formed inside the base substrate 71.

The distance sensors 72 measure distances between the distance sensors and a measurement target object. In the embodiment, the measurement target object is the ceiling surface 317 of the processing container 31. The distance sensors 72 are, for example, capacitance sensors and measure capacitances according to the distance from the jig 70 to the ceiling surface 317 of the processing container 31. Further, the distance sensors 72 are not limited to the capacitance sensors and may be other types of sensors (e.g., a laser distance sensor, an ultrasonic sensor, etc.) as long as such sensors are capable of measuring a physical quantity that changes according to the distances between the sensors and the measurement target object. The distance sensors 72 are disposed at, for example, a plurality of positions on the surface of the base substrate 71 and measure the distances between the sensors and the measurement target object at the plurality of positions, respectively. In the embodiment, the distance sensors 72 are disposed at a position at a center of the base substrate 71 and at peripheral positions of the base substrate 71. The number of the distance sensors 72 may be, for example, about 13.

The temperature sensor 73 measures a temperature of the jig 70.

The control circuit 74 is a circuit that controls each portion of the jig 70. For example, the control circuit 74 controls the distance sensors 72, measures the distance from the jig 70 to the ceiling surface 317 of the processing container 31, and stores measured distance values in the memory 75. In addition, for example, the control circuit 74 controls, using the temperature sensor 73, timings at which the distance sensors 72 measure the distance.

The memory 75 stores the measured values of the distance from the jig 70 to the ceiling surface 317 in the processing container 31 as measured by the distance sensors 72. The reading pad 76 is connected to the memory 75 and is an interface for reading the measured values from the memory 75. The reading pad 76 contacts a reading pin 94 of a reading container 90, which is described later, when reading the measured values from the memory 75.

The battery 77 supplies power to the distance sensors 72, the temperature sensor 73, and the control circuit 74. The battery 77 is detachably attached to a connector (not shown) on the surface of the base substrate 71 and is configured to be replaceable as necessary. The charging pad 78 is connected to the battery 77 and is an interface for charging the battery 77. The charging pad 78 contacts a charging pin 96 of the reading container 90, which is described later, when charging the battery 77.

The cover 79 covers the temperature sensor 73, the control circuit 74, the memory 75,

and the battery 77 mounted on the surface of the base substrate 71. The cover 79 is formed with an opening 79a at a position corresponding to the reading pad 76 and the charging pad 78, and the reading pad 76 and the charging pad 78 are exposed from the opening 79a.

### 6. Measurement Operation

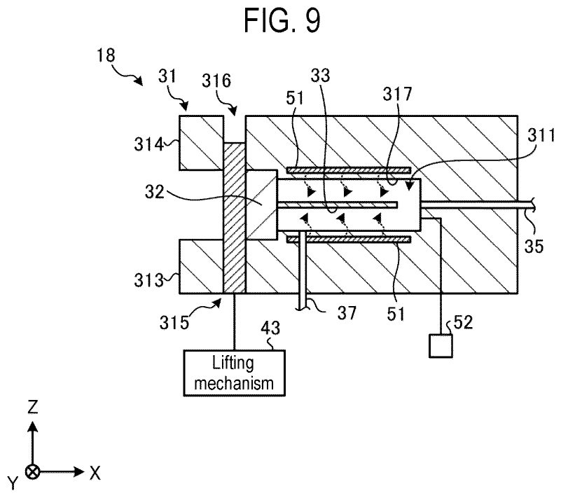

Herein, a measurement operation using the jig 70 is described with reference to FIGS. 9 to 11. FIGS. 9 to 11 are diagrams showing examples of the measurement operation using the jig 70 according to the embodiment.

The drying unit 18 heats, as shown in FIG. 9, for example, the processing space 311 of the processing container 31 by using the heater 51. In this case, the holder 33 is accommodated in the processing space 311, and the processing space 311 is sealed by the lid 32. The processing container 31 and the holder 33 are thermally deformed by heat from the heater 51. The controller 61 acquires the temperature of the processing space 311 of the processing container 31 from the temperature sensor 52.

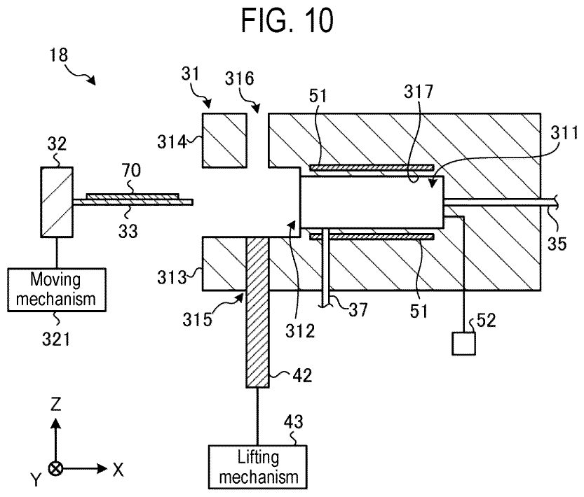

When the temperature of the processing space 311 of the processing container 31 reaches a predetermined set temperature, a loading process of the jig 70 is performed in the drying unit 18. The set temperature is, for example, the temperature of the processing space 311 assumed when the heated processing fluid is supplied from the supplier 35 to the processing space 311. The set temperature is obtained by an experiment or the like and stored in the storage 62 or the like. In the loading process of the jig 70, the drying unit 18 horizontally moves, for example, as shown in FIG. 10, the lid 32 in a negative direction of the X axis by the moving mechanism 321. As a result, the holder 33 moves together with the lid 32 from the processing area 181 to the delivery area 182. The jig 70 is taken out of the carrier C and transferred to the delivery portion 14 by the transfer device 13. Further, the jig 70 is transferred from the delivery portion 14 to the delivery area 182 by the transfer device 16, and delivered to the holder 33 in the delivery area 182 by the transfer device 16. Then, the drying unit 18 horizontally moves the lid 32 in the positive direction of the X axis by the moving mechanism 321. As a result, the jig 70 held by the holder 33 is loaded into the processing space 311 of the processing container 31, and the processing space 311 is sealed by the lid 32. The jig 70 receives heat from the heater 51 in the sealed processing space 311. As a result, the temperature of the jig 70 increases.

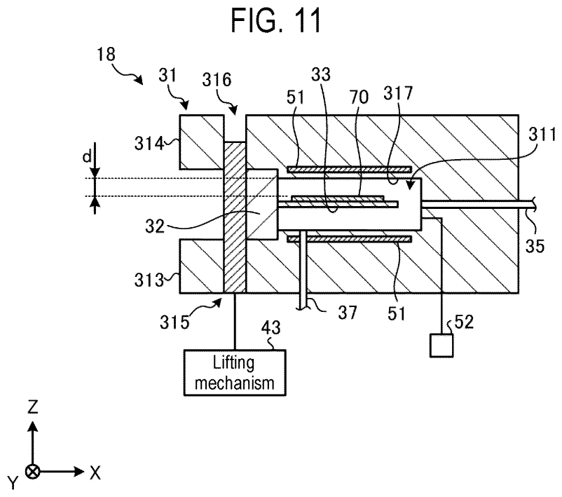

Next, the control circuit 74 of the jig 70 acquires the temperature of the jig 70 from the temperature sensor 73. When the temperature of the jig 70 reaches the above-described set temperature, the control circuit 74 measures, for example, as shown in FIG. 11, a distance d from the jig 70 to the ceiling surface 317 of the processing container 31 by using the distance sensor 72. Then, the control circuit 74 stores a value of the distance d measured by the distance sensor 72 in the memory 75.

Thus, in the substrate processing system 1 according to the embodiment, the jig 70 of the substrate shape is loaded into the processing container 31 in a state in which the processing container 31 is heated, and the distance d from the jig 70 to the ceiling surface 317 of the processing container 31 is measured by the distance sensor 72 in a state in which the jig 70 is heated.

This makes it possible to measure the distance from the jig 70 to the ceiling surface 317 of the processing container 31 with thermal deformation of the processing container 31 and the jig 70 taken into account. Since the jig 70 has substantially the same shape as the wafer W, which is a product substrate, the distance from the jig 70 to the ceiling surface 317 of the processing container 31 may be regarded as the distance from the wafer W to the ceiling surface 317 of the processing container 31. Therefore, according to the substrate processing system 1 of the embodiment, it is possible to appropriately measure the distance from the wafer W to the ceiling surface 317 of the processing container 31 in consideration of the thermal deformation of the processing container 31 and the wafer W.

### 7. Correction Operation

Herein, if the distance sensor 72 is a capacitance sensor, there is a possibility that capacitance according to the distance from the jig 70 to the ceiling surface 317 of the processing container 31, as measured by the distance sensor 72, may deviate from capacitance according to an actual distance, due to aging.

Therefore, in the embodiment, the value measured by the distance sensor 72 is corrected before the measurement operation using the jig 70 is started.

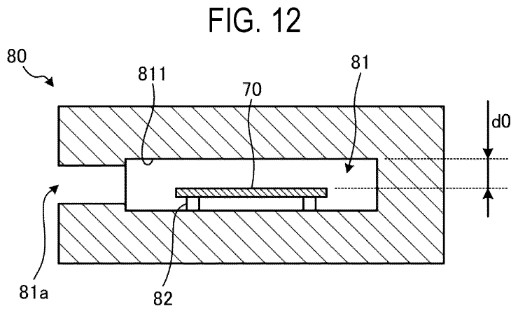

A correction operation of the measured value from the distance sensor 72 is described with reference to FIG. 12. FIG. 12 is a diagram showing an example of the correction operation of the measured value from the distance sensor 72 according to an embodiment.

First, before the measurement operation using the jig 70 is started, the jig 70 is accommodated, for example, as shown in FIG. 12, in a correction container 80. The correction container 80 includes an internal space 81 capable of accommodating the jig 70. The correction container 80 has a circular shape when viewed in a plan view and is formed with an opening 81a on a side thereof. The jig 70 is loaded into the internal space 81 of the correction container 80 from the opening 81a and placed on a support 82 provided on a bottom surface of the internal space 81. A distance from the jig 70 accommodated in the correction container 80 to a ceiling surface 811 of the internal space 81 is a predetermined reference distance d0. The reference distance d0 is a distance at which a laminar flow of a processing fluid flowing in a predetermined direction is formed around the jig 70 under an assumption that a heated processing fluid is supplied to the internal space 81, similar to the processing fluid of the drying unit 18, and the reference distance d0 is determined by an experiment or the like.

When the jig 70 is accommodated in the correction container 80, the control circuit 74 of the jig 70 measures the distance from the jig 70 to the ceiling surface 811 of the correction container 80 by using the distance sensor 72. Then, when a difference between a capacitance according to the distance from the jig 70 to the ceiling surface 811 of the correction container 80, as measured by the distance sensor 72, and a capacitance according to the reference distance d0 deviates from an allowable range, the control circuit 74 corrects the capacitance measured by the distance sensor 72. That is, the control circuit 74 corrects the capacitance measured by the distance sensor 72 to the capacitance according to the reference distance d0. Thereby, it is possible to suppress a problem of the distance sensor 72 caused by aging.

### 8. Reading Operation

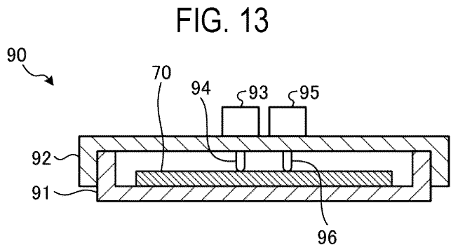

Next, a reading operation of the measured value from the jig 70 is described with reference to FIG. 13. FIG. 13 is a diagram showing an example of the reading operation of the measured value from the jig 70 according to an embodiment.

After the measurement operation using the jig 70 is completed, the jig 70 is accommodated, for example, as shown in FIG. 13, in a reading container 90 (an example of an accommodation container). The reading container 90 includes a container body 91 of a box shape that opens upward and a lid member 92 and forms an internal space capable of accommodating the jig 70 by combining the lid member 92 with the container body 91. The jig 70 is placed on a bottom surface of the container body 91. Then, as an opening of the container body 91 is closed by the lid member 92, the jig 70 is accommodated in the internal space.

The lid member 92 is provided with a reading connector 93 (an example of a first connector) and the reading pin 94 (an example of a first pin). The reading connector 93 is an interface for reading the measured value from the memory 75 of the jig 70. The reading connector 93 is connected to a reader such as, for example, an information processor, when reading the measured value from the memory 75. The reading pin 94 is electrically connected to the reading connector 93. The reading pin 94 contacts the reading pad 76 of the jig 70 accommodated in the reading container 90. This allows the reader connected to the reading connector 93 to read the measured value from the memory 75 into the reader via the reading pad 76 and the reading pin 94.

The lid member 92 is provided with a charging connector 95 (an example of a second connector) and the charging pin 96 (an example of a second pin). The charging connector 95 is an interface for charging the battery 77 of the jig 70. The charging connector 95 is connected to an external power source, such as a charger, when charging the battery 77. The charging pin 96 is electrically connected to the charging connector 95. The charging pin 96 contacts the charging pad 78 of the jig 70 accommodated in the reading container 90. This allows the external power source connected to the charging connector 95 to charge the battery 77 from the external power source via the charging pad 78 and the charging pin 96, in parallel with reading the measured value into the reader.

### 9. Flow of Distance Measurement Process

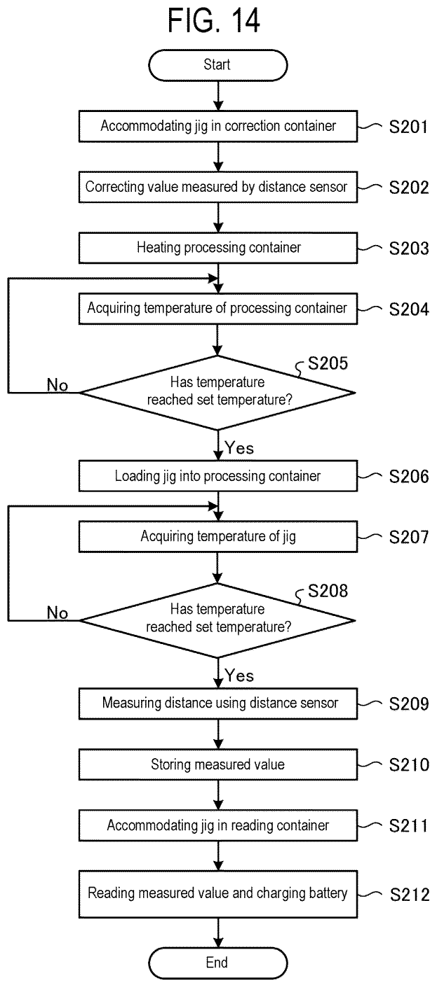

Next, an example of a flow of the distance measurement process according to an embodiment is described with reference to FIG. 14. FIG. 14 is a flowchart showing the example of the flow of the distance measurement process according to the embodiment.

A user of the substrate processing system 1 accommodates the jig 70 in the correction container 80 (step S201). The control circuit 74 of the jig 70 corrects the capacitance according to the distance from the jig 70 to the ceiling surface 811 of the correction container 80, as measured by the distance sensor 72, to the capacitance according to the reference distance d0 (step S202). After correction, the jig 70 is accommodated in the carrier C.

The controller 61 controls the transfer devices 13 and 16 to take the jig 70 out of the carrier C and transfer the jig 70 to the delivery area 182 of the drying unit 18 via the delivery portion 14.

Next, the controller 61 heats the processing space 311 of the processing container 31 by using the heater 51 (step S203). Thereby, the temperature of the processing container 31 increases. Heating by the heater 51 is continued until step $210 is completed.

Next, the controller 61 acquires the temperature of the processing container 31 from the temperature sensor 52 (step S204). Then, the controller 61 determines whether the temperature of the processing container 31 acquired in step S204 has reached a set temperature (step S205).

If the temperature of the processing container 31 has not reached the set temperature (step S205; “No”), the controller 61 returns the process to step S204. On the other hand, if the temperature of the processing container 31 has reached the set temperature (step S205; “Yes”), the controller 61 controls the transfer device 16 and the moving mechanism 321 to load the jig 70 from the delivery area 182 into the processing container 31 (step S206). Thereby, the temperature of the jig 70 increases.

Next, the control circuit 74 of the jig 70 acquires the temperature of the jig 70 from the temperature sensor 73 (step S207). Then, the control circuit 74 determines whether the temperature of the jig 70 acquired in step S207 has reached a set temperature (step S208).

If the temperature of the jig 70 has not reached the set temperature (step S208; “No”), the control circuit 74 returns the process to step S207. On the other hand, if the temperature of the jig 70 has reached the set temperature (step S208; “Yes”), the control circuit 74 measures the distance d from the jig 70 to the ceiling surface 317 of the processing container 31 by using the distance sensor 72 (step S209). Then, the control circuit 74 stores the value of the distance d measured by the distance sensor 72 in the memory 75 (step S210).

Next, the controller 61 controls the transfer device 16 and the moving mechanism 321 to unload the jig 70 from the drying unit 18.

Next, the user of the substrate processing system 1 accommodates the jig 70 in the reading container 90 (step S211). A reader is connected to the reading connector 93 of the reading container 90. The reader connected to the reading connector 93 reads the measured value from the memory 75 into the reader via the reading pad 76 and the reading pin 94 (step S212). Also, an external power source is connected to the charging connector 95 of the reading container 90. The external power source connected to the charging connector 95 charges the battery 77 from the external power source via the charging pad 78 and the charging pin 96, in parallel with reading the measured value into the reader (step S212).

As described above, a distance measurement method according to the embodiment includes a heating process, a loading process, and a measurement process. In the heating process, a processing container (e.g., the processing container 31) capable of accommodating a substrate (e.g., the wafer W) is heated. In the loading process, a jig of a substrate shape (e.g., the jig 70) is loaded into the processing container in a state in which the processing container is heated. In the measurement process, a distance (e.g., the distance d) from the jig to a ceiling surface (e.g., the ceiling surface 317) of the processing container is measured by a distance sensor (e.g., the distance sensor 72) provided in the jig.

Therefore, according to the distance measurement method of the embodiment, it is possible to appropriately measure a distance from the substrate to a ceiling surface of the processing container.

The measurement process may include measuring the distance from the jig to the ceiling surface of the processing container by using the distance sensor in a state in which the jig loaded into the processing container is heated. Thereby, it is possible to appropriately measure the distance from the substrate to the ceiling surface of the processing container in consideration of the thermal deformation of the processing container and the jig.

The distance sensor may be a capacitance sensor and may measure a capacitance according to the distance from the jig to the ceiling surface of the processing container. This allows measurement using the capacitance sensor with excellent heat resistance.

In the distance measurement method according to the embodiment, before the measurement process, the jig may be accommodated in a first accommodation container (e.g., the correction container 80), which is capable of accommodating the jig and whose distance from the accommodated jig to the ceiling surface (e.g., the ceiling surface 811) is a predetermined reference distance (e.g., the reference distance d0). Then, in the distance measurement method according to the embodiment, the capacitance according to the distance from the jig to the ceiling surface of the first accommodation container, as measured by the distance sensor, may be corrected to a capacitance according to the reference distance. This makes it possible to suppress a problem of the distance sensor caused by aging.

In the measurement process, a measured value of the distance from the jig to the ceiling surface of the processing container, as measured by the distance sensor, may be stored in a memory (e.g., the memory 75) provided in the jig. In addition, in the distance measurement method according to the embodiment, after the measurement process, the jig may be accommodated in a second accommodation container (e.g., the reading container 90), which is capable of accommodating the jig and includes a first connector (e.g., the reading connector 93) connected to a reader. In the distance measurement method according to the embodiment, the measured value may be read from the memory into the reader in a state in which the jig is accommodated in the second accommodation container. Specifically, the second accommodation container may include a first pin that is capable of contacting a first pad (e.g., the reading pad 76) provided on the accommodated jig and is electrically connected to the first connector. In the process of reading the measured value, the measured value may be read from the memory into the reader via the first pad and the first pin. This makes it possible to efficiently read the measured value into the reader.

The second accommodation container may include a second connector (the charging connector 95) connected to an external power source. In addition, the distance measurement method according to the embodiment may include charging a battery (e.g., the battery 77) provided in the jig from the external power source, in parallel with the process of reading the measured value. Specifically, the second container may include a second pin (e.g., the charging pin 96) that is capable of contacting a second pad (e.g., the charging pad 78) provided in the accommodated jig and is electrically connected to the second connector. In the process of charging, the battery may be charged from the external power source via the second pad and the second pin. This makes it possible to efficiently charge the battery.

A distance measurement system according to the embodiment (e.g., the substrate processing system 1) includes a processing container (e.g., the processing container 31), a jig (e.g., the jig 70), and an accommodation container (e.g., the reading container 90). The processing container is capable of accommodating a substrate. The jig is a jig of a substrate shape that is loaded into the processing container in a state in which the processing container is heated. The jig is provided with a distance sensor (e.g., the distance sensor 72) that measures a distance to a ceiling surface (e.g., the ceiling surface 317) of the processing container, and a memory (e.g., the memory 75) that stores a measured value from the distance sensor. The accommodation container is capable of accommodating the jig and includes a first connector (e.g., the reading connector 93) connected to a reader that reads the measured value from the memory.

Therefore, according to the distance measurement system of the embodiment, it is possible to appropriately measure a distance from the substrate to the ceiling surface of the processing container and efficiently read the measured value into the reader.

The accommodation container may include a second connector (e.g., the charging connector 95) connected to an external power source that charges a battery (e.g., the battery 77) provided in the jig. This makes it possible to efficiently charge the battery.

A substrate processing apparatus (e.g., the substrate processing system 1) according to the embodiment includes a processing container (e.g., the processing container 31), a transfer device (e.g., the transfer device 16), and a controller (e.g., the controller 61). The processing container is capable of accommodating a substrate (e.g., the wafer W). The transfer device transfers a jig of a substrate shape (e.g., the jig 70) to a delivery area (e.g., the delivery area 182) adjacent to the processing container. The controller controls each portion to execute a distance measurement method including a heating process, a loading process, and a measurement process. The heating process includes heating the processing container. The loading process includes loading the jig into the processing container in a state in which the processing container is heated. The measurement process includes measuring a distance (e.g., the distance d) from the jig to a ceiling surface (e.g., the ceiling surface 317) of the processing container by using a distance sensor (e.g., the distance sensor 72) provided in the jig.

Therefore, according to the substrate processing apparatus of the embodiment, it is possible to appropriately measure a distance from the substrate to the ceiling surface of the processing container.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A distance measurement method, comprising:
heating a processing container capable of accommodating a substrate;
loading a jig of a substrate shape into the processing container in a state in which the processing container is heated; and
measuring a distance from the jig to a ceiling surface of the processing container by using a distance sensor provided in the jig.

2. The distance measurement method of claim 1, wherein the measuring includes measuring the distance from the jig to the ceiling surface of the processing container by using the distance sensor in a state in which the jig loaded into the processing container is heated.

3. The distance measurement method of claim 1, wherein the distance sensor is a capacitance sensor and measures a capacitance according to the distance from the jig to the ceiling surface of the processing container.

4. The distance measurement method of claim 1, further comprising, before the measuring:
accommodating the jig in a first accommodation container, which is capable of accommodating the jig, wherein a distance from the accommodated jig to a ceiling surface of the first accommodation container is a predetermined reference distance; and
correcting a capacitance, measured by the distance sensor according to the distance from the jig to the ceiling surface of the first accommodation container, to a capacitance according to the reference distance.

5. The distance measurement method of claim 1, wherein the measuring further includes storing a measured value of the distance from the jig to the ceiling surface of the processing container, as measured by the distance sensor, in a memory provided in the jig, and
wherein the distance measurement method further comprises, after the measuring:
accommodating the jig in a second accommodation container, which is capable of accommodating the jig and includes a first connector connected to a reader; and
reading the measured value from the memory into the reader in a state in which the jig is accommodated in the second accommodation container.

6. The distance measurement method of claim 5, wherein the second accommodation container includes a first pin that is capable of contacting a first pad provided in the accommodated jig and is electrically connected to the first connector; and
wherein the reading the measured value includes reading the measured value from the memory into the reader via the first pad and the first pin.

7. The distance measurement method of claim 5, wherein the second accommodation container includes a second connector connected to an external power source, and
wherein the distance measurement method further comprises:
charging a battery provided in the jig from the external power source, in parallel with the reading the measured value.

8. The distance measurement method of claim 7, wherein the second accommodation container includes a second pin that is capable of contacting a second pad provided in the accommodated jig and is electrically connected to the second connector, and
wherein the charging includes charging the battery from the external power source via the second pad and the second pin.

9. A distance measurement system, comprising:
a processing container which is capable of accommodating a substrate;
a jig of a substrate shape which is loaded into the processing container, in a state in which the processing container is heated, and is provided with a distance sensor configured to measure a distance to a ceiling surface of the processing container and a memory configured to store a measured value from the distance sensor; and
an accommodation container which is capable of accommodating the jig and includes a first connector connected to a reader configured to read the measured value from the memory.

10. The distance measurement system of claim 9, wherein the accommodation container includes a second connector connected to an external power source configured to charge a battery provided in the jig.

11. A substrate processing apparatus, comprising:
a processing container which is capable of accommodating a substrate;
a transfer device which is configured to transfer a jig of a substrate shape to a delivery area adjacent to the processing container; and
a controller,
wherein the controller is configured to control the processing container and the transfer device to execute a distance measurement method including:
heating the processing container;
loading the jig into the processing container from the delivery area in a state in which the processing container is heated; and
measuring a distance from the jig to a ceiling surface of the processing container by using a distance sensor provided in the jig.
